(19) United States
(12) Patent Application Publication
(10) Pub. No.: US 2024/0312919 A1
(43) Pub. Date: Sep. 19, 2024

(54) INTERPOSER SOLUTION FOR HIGH CORE COUNT COMPUTE PLATFORMS

(71) Applicant: Intel Corporation, Santa Clara, CA (US)

(72) Inventor: Pezhman MONADGEMI, Santa Clara, CA (US)

(21) Appl. No.: 18/120,910

(22) Filed: Mar. 13, 2023

(51) Int. Cl. H01L 23/538; H01L 25/00; H01L 25/065

(52) U.S. Cl. CPC H01L 23/5386; H01L 25/0655; H01L 25/50; H01L 23/5381; H01L 24/13; H01L 24/16; H01L 2224/13147; H01L 2224/16225; H01L 2924/1432; H01L 2924/1434

(57) ABSTRACT

Embodiments disclosed herein include a multi-die module. In an embodiment, the multi-die module comprises an interposer, where the interposer comprises a first region and a second region. In an embodiment, the first region is spaced apart from the second region by a saw street. In an embodiment, a first die is over the interposer, where the first die is positioned over the saw street. In an embodiment, a second die is adjacent to a first end of the first die, and a third die is adjacent to a second end of the first die opposite from the first end.

### TECHNICAL FIELD

Embodiments of the present disclosure relate to electronic packages, and more particularly to packaging architectures that include an interposer with a multiple reticle form factor.

### BACKGROUND

High core count compute and graphics devices used in high performance computing (HPC) platforms may have large die complexes, such as above 1,000 mm². In some instances, the cores may be provided over an interposer, such as a silicon or glass interposer. The silicon interposer allows for high density routing to be provided between different cores and system on a chip (SoC) or high bandwidth memory (HBM), or between field programmable gate arrays (FPGA). However, the large footprint of existing die complexes is larger than the existing reticle size limit used to form the interposer substrates. For example, a reticle size limit for the fabrication of interposers may be approximately 25 mm by approximately 30 mm. As such, a multiple exposure solution is needed (e.g., a 2× solution or a 4× solution may be used), known as reticle field stitching or reticle stitching. However, multiple exposure solutions require precise alignment in order to couple the two exposure regions together. As such, cost to implement such solutions are high.

In another option, a co-embedded bridge solution is used in conjunction with the interposer approach. In such an example, two 1× reticle size interposers are joined together by a plurality of embedded bridge architectures in the center of package. However, embedded bridge solutions are typically lower yielding, have coarser bump pitch than interposer and lead to additional costs. Additionally, embedded bridge architectures suffer from bandwidth degradation due to the fan-out and fan-in needed to route the signals between two interposers. To maintain the same bandwidth with embedded bridge architectures, the frequency of wires needs to be increased, which results in higher power. At the same time, memory latency is degraded due to the increased interconnect length needed for pitch translation. Larger than 1× reticle size architectures having an SoC die in the middle require splitting the die into two halves with each half sitting above an interposer, joined by the bridge. Splitting high-speed memory controller blocks and routing data traffic through the embedded bridge degrades latency.

### BRIEF DESCRIPTION OF THE DRAWINGS

FIG. 1A is a cross-sectional illustration of a multi-die module with a 2× reticle size design.

FIG. 1B is a plan view illustration of a multi-die module with a 2× reticle size design.

FIG. 2A is a cross-sectional illustration of a multi-die module with a 2× reticle size design wherein a first reticle region is spaced apart from the second reticle region by a saw street, in accordance with an embodiment.

FIG. 2B is a zoomed in illustration of the saw street between the reticle regions, in accordance with an embodiment.

FIG. 3A is a cross-sectional illustration of a multi-die module with a 2× reticle size design where the first reticle region is spaced apart from the second reticle region by a saw street that does not include a seal ring, in accordance with an embodiment.

FIG. 3B is a zoomed in illustration of the saw street between the reticle regions, in accordance with an embodiment.

FIG. 4A is a plan view illustration of a multi-die module with a 2× reticle size design, where the first reticle region is spaced apart from the second reticle region by a saw street, and where a system on a chip (SoC) is across the saw street and compute dies are adjacent to opposite sides of the SoC, in accordance with an embodiment.

FIG. 4B is a plan view illustration of a multi-die module with a 2× reticle size design, where the first reticle region is spaced apart from the second reticle region by a saw street, and where compute dies span across the saw street and SoCs are adjacent to the compute dies.

FIG. 5A is a cross-sectional illustration of a multi-die module with an interposer that includes a first region that is separated from a second region by a saw street with a seal ring, in accordance with an embodiment.

FIG. 5B is a cross-sectional illustration of a multi-die module with an interposer that includes a first region that is separated from a second region by a saw street without a seal ring, in accordance with an embodiment.

FIG. 5C is a cross-sectional illustration of a computing system with a multi-die module that includes at least a 2× reticle size layout in the interposer, in accordance with an embodiment.

FIGS. 6A-6I are cross-sectional illustrations depicting a process for forming a multi-die module that includes an interposer with a first region and a second region that are separated by a saw street, in accordance with an embodiment.

FIG. 7A is a plan view illustration of an interposer that includes a first region that is a mirror image of a second region, in accordance with an embodiment.

FIG. 7B is a plan view illustration of an interposer that includes a first region that is different than a second region, in accordance with an embodiment.

FIG. 8 is a schematic of a computing device built in accordance with an embodiment.

### EMBODIMENTS OF THE PRESENT DISCLOSURE

Described herein are packaging architectures that include an interposer with a multiple reticle form factor, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

An interposer is used in many multi-die architectures. The interposer may comprise a silicon interposer or other materials that are suitable for providing high density routing between two or more compute dies, systems on a chip (SoCs), or the like. The interposers are patterned and fabricated using a photolithography system. In one such implementation a reticle is used in order to lithographically pattern photoimageable layer(s) over the interposer. However, as the form factor of the multi-die architectures increase, the reticle size limit of such patterning processes may be exceeded. That is, the standard reticle size is no longer sufficient to manufacture the interposers. As such, new tooling may be needed in order to accommodate a larger reticle size. This may be prohibitively expensive.

Accordingly, reticle field stitching solutions may be used as a substitute. In a reticle stitching architecture, the reticle may be exposed over the interposer substrate two or more times. A double exposure (e.g., a 2× form factor) may involve exposing the interposer with a reticle to form a first region, and then exposing a second region adjacent to the first region with the reticle. In some instances, the same reticle may be used to form the first region and the second region, though different reticles may also be used in some instances (e.g., when the first region has a different pattern than the second region).

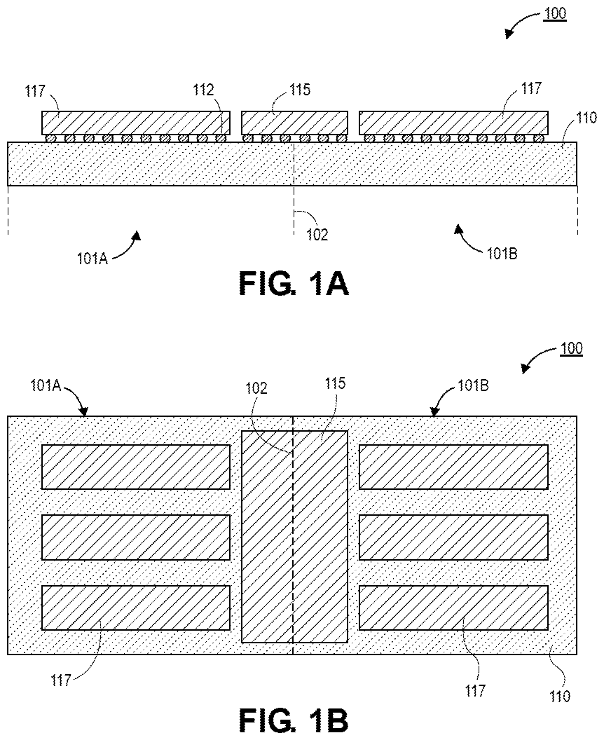

Referring now to FIG. 1A a cross-sectional illustration of a multi-die module 100 is shown as an example. As shown, the multi-die module 100 may include an interposer 110. The interposer 110 may comprise a first region 101A that is adjacent to a second region 101B. The first region 101A may be separated from the second region by a plane 102. More particularly, the first region 101A has an edge that directly contacts the edge of the second region 101B. That is, there is no voided space between the first region 101A and the second region 101B. Such an architecture relies on precise alignment between the two regions 101A and 101B. This results in expensive processing.

As shown, a plurality of dies 117 and 115 may be provided over the top surface of the interposer 110. For example, interconnects 112 may couple the dies 117 and 115 to the interposer 110. The die 115 may be a system on a chip (SoC), a memory die, or any other type of die, and the dies 117 may be compute dies, such as central processing units (CPUs), graphics processing units (GPUs), communication dies, or any other type of compute die. As shown, the die 115 may span across the plane 102 between the first region 101A and the second region 101B.

Referring now to FIG. 1B, a plan view illustration of a multi-die module 100 is shown as an example. The multi-die module 100 may be formed upon an interposer 110. The interposer 110 may have a form factor that exceeds that of a standard reticle for patterning the interposer 110. For example, in FIG. 1B, a first region 101A and a second region 101B are both lined up along a plane 102. That is, the interposer 110 may be considered a 2× interposer. Though, larger form factors (e.g., 3×, 4×, etc.) may also be used.

An SoC 115 or the like may be provided over the plane 102. That is, the SoC 115 may have a footprint that covers a portion of both the first region 101A and the second region 101B. The multi-die module 100 may further comprise compute dies 117. Each compute die 117 may be isolated to one of the first region 101A or the second region 101B. The compute dies 117 may be communicatively coupled to the SoC 115 through conductive routing (not shown) fabricated into and/or on the interposer 110. In this way, the plurality of dies 117 and 115 may be communicatively coupled together even when the interposer exceeds the reticle size limit.

However, architectures such as those shown in FIGS. 1A and 1B are limited in that expensive alignment processes are needed in order to properly align the first region 101A to the second region 101B. Accordingly, embodiments disclosed herein include interposers with multi-reticle form factors (e.g., 2×, 3×, 4×, etc.) that include saw streets between each of the reticle regions. The saw streets may be voided regions of the interposer. That is, there may not be any functional circuitry in the saw streets. However, unlike traditional saw streets, the saw streets between the reticle regions are not removed (e.g., with a singulation process). The presence of the saw streets allows for an additional buffer between the reticle exposure regions, and increases tolerance to misalignment.

In some embodiments, the saw streets are substantially similar to the saw streets around the perimeter of the interposer. That is, the intervening saw streets may include a voided region that is lined by a seal ring. In other embodiments, the intervening saw streets may be structurally different than the outer saw streets. For example, the intervening saw streets may not include a seal ring in some embodiments.

In a particular embodiment, the reticle regions are electrically isolated from each other within the interposer. That is, on the interposer, the electrical circuitry of a first reticle region is not connected to the electrical circuitry of a second reticle region. Though, it is to be appreciated that overlying dies may electrically couple the first reticle region to the second reticle region in some embodiments.

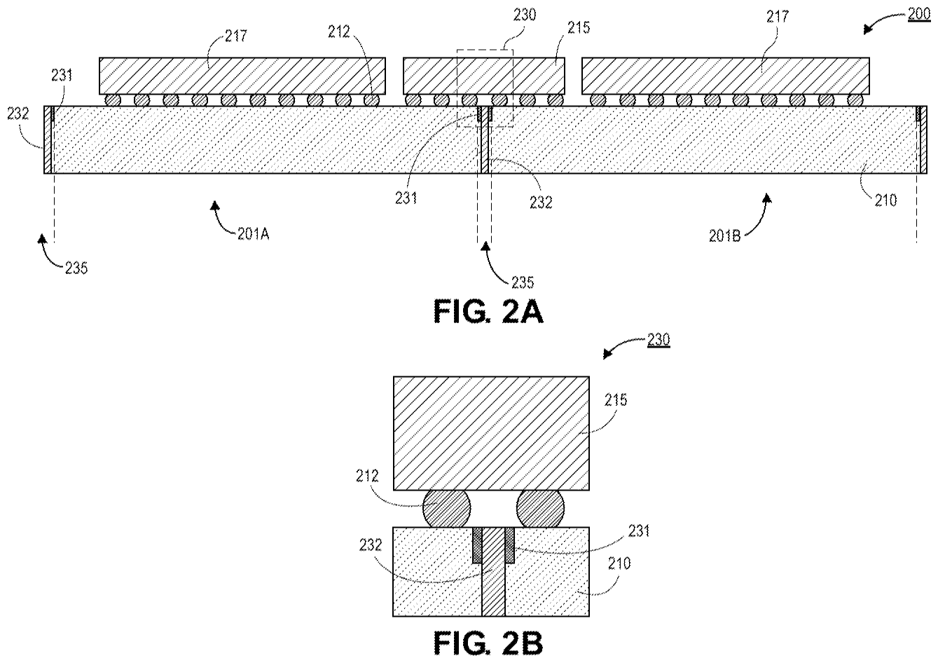

Referring now to FIG. 2A, a cross-sectional illustration of a multi-die module 200 is shown, in accordance with an embodiment. In an embodiment, the multi-die module 200 may comprise an interposer 210. The interposer 210 may be a substrate on which high density routing (not shown) is formed in order to electrically couple together the overlying dies 215 and 217. In an embodiment, the interposer 210 may comprise silicon. Though, other materials may also be used in some embodiments.

In an embodiment, the form factor of the interposer 210 may be larger than a standard reticle form factor. For example, reticles used in existing fabrication environments may have a footprint of approximately 25 mm by approximately 30 mm. More particularly, the reticle may have a footprint that is 26 mm by 33 mm. In an embodiment, the interposer 210 may have a form factor that is approximately an integer multiple of the form factor of the reticle (e.g., 2×, 3×, 4×, etc.). As used herein, “approximately” may refer to a range of values within ten percent of the stated value. For example, approximately 25 mm may refer to a range between 22.5 mm and 27.5 mm.

In the case of the interposer 210 shown in FIG. 2A, the interposer 210 has a 2× reticle size form factor. As such, a first reticle region 201A and a second reticle region 201B are formed on the interposer 210. The first reticle region 201A (also referred to as first region 201A) may be spaced apart from the second reticle region 2021B (also referred to as second region 201B) by a saw street 235. The saw street 235 may be a voided region of the interposer 210 without any functional circuitry. Though, in some instances test features or the like may be provided in the saw street 235. While referred to as a “saw street” herein, the region 235 may sometimes be referred to as a “street”, a “scribe line”, a “kerf line”, or the like. Portions of saw streets 235 may also be provided along the edges of the interposer 210. In an embodiment, the saw street 235 may have a width that is approximately 10 μm or less.

In an embodiment, the saw street 235 may include a voided region 232. The voided region 232 may comprise substantially silicon or other material of the interposer 210 substrate. That is, the saw street 235 may be the same material as the substrate. As such, there may be no discernable boundary between the voided region 232 and the remainder of the interposer 210. The differentiating factor is that, in some embodiments, there may be no conductive circuitry in the voided region 232. However, in some instances, a seal ring 231 may be provided along the outer sidewalls of the voided region 232. The seal ring 231 may comprise an oxide, a nitride, a metal, or any other suitable material that is different than the material of the interposer 210 substrate. The seal ring 231 protects the interposer 210 from cracks that may otherwise propagate out of saw street 235 during or after singulation. The seal ring 231 in FIG. 2A extends partially through a thickness of the interposer 210, though embodiments are not limited to such structures. While the saw street 235 between the first region 201A and the second region 201B is not singulated, the saw street 235 may still have the protective seal ring 231. The presence of the seal ring 231 may also be used to indicate the presence of the voided region 232.

In an embodiment, a plurality of dies 215 and 217 may be provided over the interposer 210. The dies 215 and 217 may be coupled to the interposer 210 through interconnects 212. The interconnects 212 may be solder balls, copper bumps, or any other suitable first level interconnect (FLI) architecture. In an embodiment, conductive routing (not shown) in the first region 201A and the second region 201B may electrically couple the dies 217 to the die 215. In some embodiments, conductive routing in the first region 201A may be electrically coupled to conductive routing in the second region 201B by the die 215, as opposed to being coupled directly in the interposer 210 across the saw street 235.

In an embodiment, the dies 217 may be any suitable compute dies. For example, the dies 217 may comprise CPUs, GPUs, XPUs, communication dies, or the like. In some instances the dies 217 may be referred to as “chips” or “chiplets”. In an embodiment, the die 215 may be a hub die, such as an SoC, a memory die, or any other suitable die that is configured to be coupled to a plurality of dies 217.

In an embodiment, the die 215 may extend across the saw street 235. The die 215 may be positioned so that none of the interconnects 212 to the die 215 land over the saw street 235. For ease of reference, a zoomed in illustration of region 230 is shown in FIG. 2B. As shown, the die 215 is coupled to the interposer 210 through interconnects 212. However, none of the interconnects 212 are provided over the seal ring 231 or the voided region 232. This is because there may not be any functional circuitry that is provided in the voided region 232.

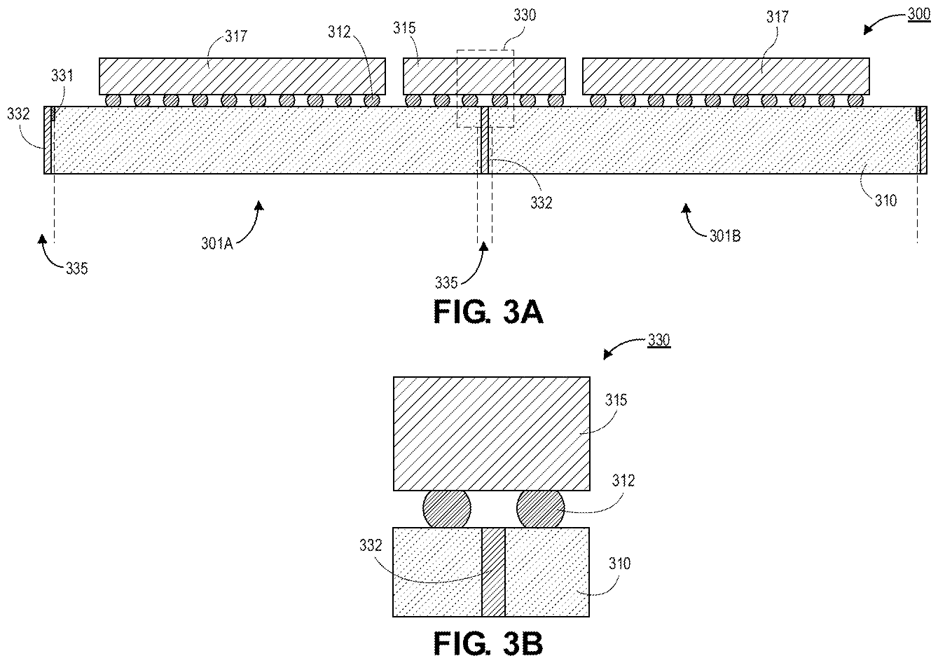

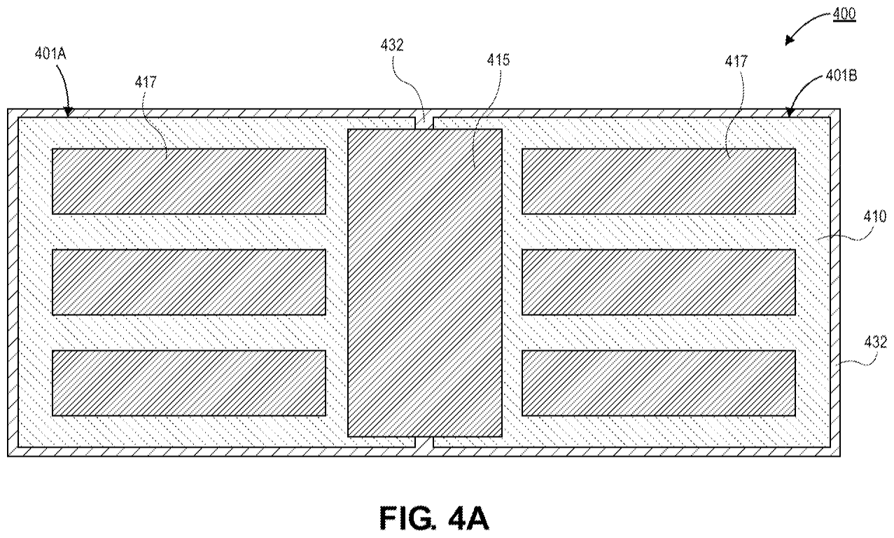

Referring now to FIG. 3A, a cross-sectional illustration of a multi-die module 300 is shown, in accordance with an additional embodiment. The multi-die module 300 may comprise an interposer 310. A plurality of dies 315 and 317 may be coupled to the interposer 310 by interconnects 312. The dies 315 and 317 may be similar to the types of dies described above with respect to FIG. 2A.

In an embodiment, a first region 301A and a second region 301B may be separated from each other by a saw street 335. The saw street 335 may include a voided region 332. However, in contrast to the embodiment described above, the saw street 335 between the first region 301A and the second region 301B may omit the seal ring. The saw streets 335 at the perimeter of the interposer 310 may still have seal rings 331 in some embodiments. The central saw street 335 below the die 315 may omit the seal ring 331 since there is no cutting of the voided region 332. Since the outer saw streets 335 are still cut, the outer saw streets 335 may include the seal ring 331.

FIG. 3B shows a zoomed in cross-sectional illustration of the region 330 in FIG. 3A. As shown, a die 315 is coupled to the interposer 310 by interconnects 312. The die 315 spans across a voided region 332. The interconnects 312 may be absent from over the voided region 332 since there may not be any active circuitry in the voided region 332. FIG. 3B illustrates the embodiment where the seal ring 331 is omitted from the central saw street 335. That is, the saw street 335 may comprise only the voided region 332. Without the presence of the seal ring 331, the voided region 332 may not have discernable boundaries. However, the voided region 332 is considered to be the region under the die 315 (which may be at a centerline of the die 315) that is substantially free from electrical circuitry through a thickness of the interposer 310.

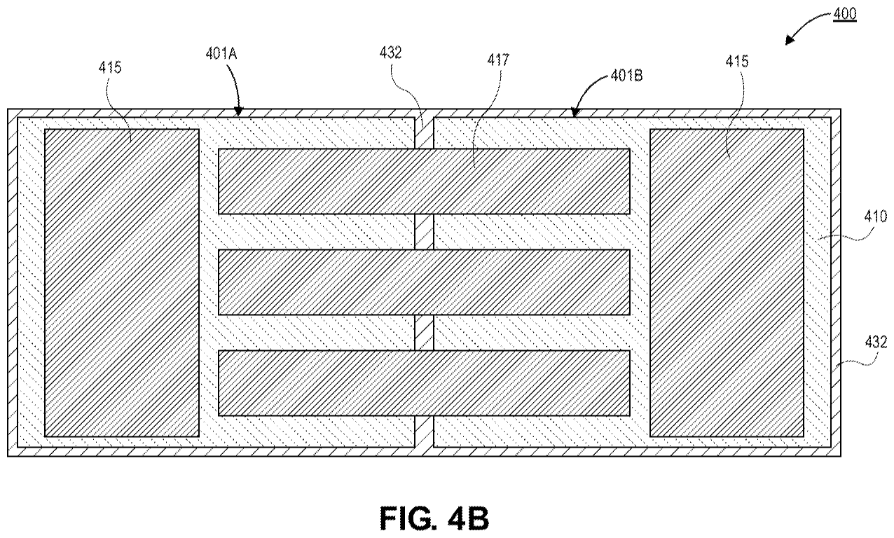

Referring now to FIG. 4A, a plan view illustration of a multi-die module 400 is shown, in accordance with an embodiment. As shown, an interposer 410 may be provided below a plurality of dies 415 and 417. The die 415 may be a hub die, an SoC, or the like. In an embodiment, the plurality of dies 417 may be electrically coupled to the die 415 through conductive routing (not shown) on the interposer 410. A first column of dies 417 may be provided along a first edge of the die 415 in a first region 401A, and a second column of dies 417 may be provided along a second edge of the die 415 in a second region 401B. The plurality of dies 417 may be compute dies, such as those described above.

In an embodiment, the first region 401A may be separated from the second region by a voided region 432. The voided region 432 may be part of a saw street that passes through a thickness of the interposer 410. While referred to as a saw street, it is to be appreciated that the central voided region 432 may not be actually cut or otherwise singulated. In an embodiment, the die 415 may span across the voided region 432. In a particular embodiment, the voided region 432 is provided at a centerline of the die 415. Though, in other embodiments the voided region 432 may be offset from a centerline of the die 415. Additionally, the voided region 432 may separate the first region 401A and the second region 401B into two regions of substantially equal area. In an embodiment, the voided region 432 may also surround a perimeter of the interposer 410. The voided regions 432 around the perimeter of the interposer 410 may be part of saw streets that have been singulated. That is, a portion of the saw street may be removed from the perimeter of the interposer 410.

The voided regions 432 shown in FIG. 4A are illustrated without a seal ring. However, it is to be appreciated that seal rings may also be included as part of the saw streets around the voided regions 432. Along the outer voided regions, a single sided seal ring may be provided between the voided region 432 and the remaining portion of the interposer 410. For the central voided region 432 that passes below the die 415, the seal ring may be provided on both sides (i.e., the left side and the right side, as viewed in FIG. 4A).

Referring now to FIG. 4B, a plan view illustration of a multi-die module 400 is shown, in accordance with an additional embodiment. As shown, a plurality of compute dies 417 may be arranged in a column that passes across the central voided region 432. One or more dies 415 may be provided adjacent to the column of compute dies 417. The dies 415 may be hub dies, SoCs, memory dies, or the like. Such an architecture may be referred to as a distributed-IO architecture in some embodiments.

The voided regions 432 shown in FIG. 4B are illustrated without a seal ring. However, it is to be appreciated that seal rings may also be included as part of the saw streets around the voided regions 432. Along the outer voided regions, a single sided seal ring may be provided between the voided region 432 and the remaining portion of the interposer 410. For the central voided region 432 that passes below the dies 417, the seal ring may be provided on both sides (i.e., the left side and the right side, as viewed in FIG. 4B).

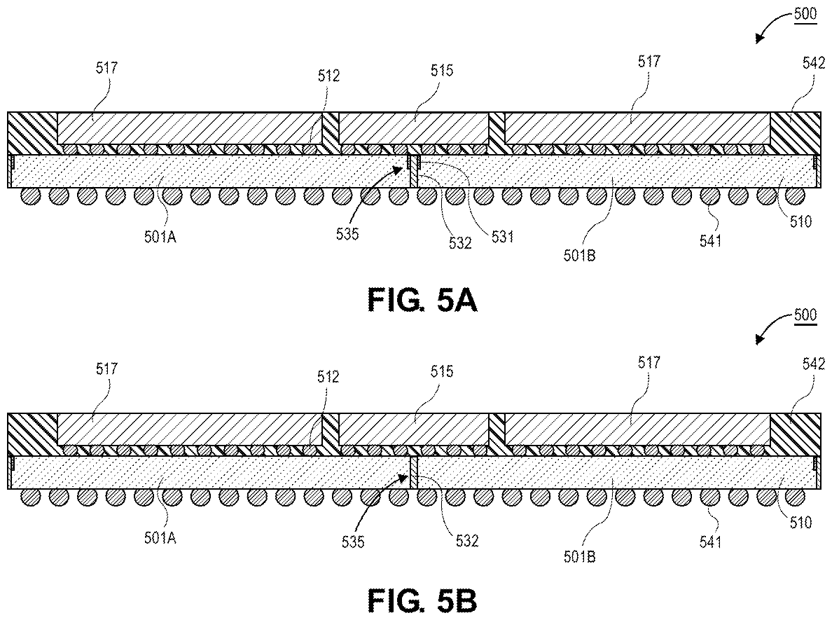

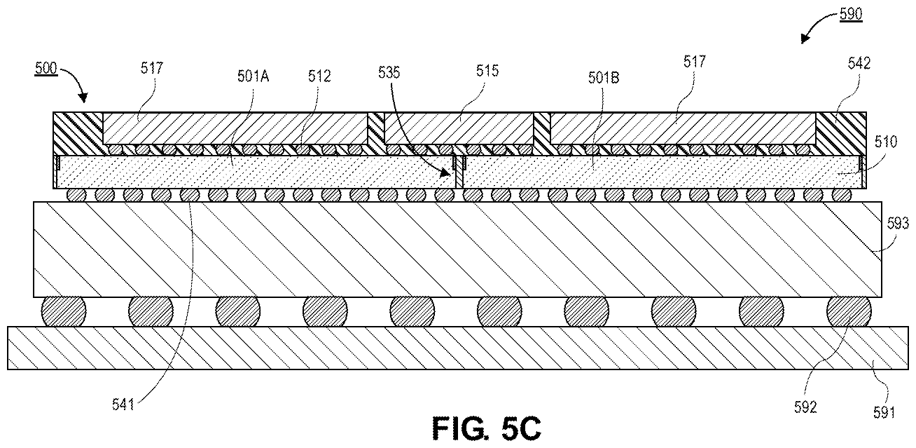

Referring now to FIG. 5A, a cross-sectional illustration of a multi-die module 500 is shown, in accordance with an additional embodiment. In an embodiment, the multi-die module 500 comprises an interposer 510. The interposer 510 may include a first region 501A and a second region 501B. The first region 501A and the second region 501B may be separated from each other by a saw street 535. The saw street 535 may comprise a voided region 532 and a seal ring 531.

In an embodiment, a die 515 is provided over the saw street 535. The die 515 may be coupled to adjacent dies 517 through conductive routing (not shown) on the interposer 510. The dies 515 and 517 may be coupled to the interposer 510 through interconnects 512. In an embodiment, an overmold 542 may be provided around the dies 515 and 517, and around the interconnects 512. In other embodiments, a capillary underfill (CUF) may be provided around the interconnects 512 instead of the overmold 542.

In an embodiment, the interposer 510 may comprise interconnects 541 on a side opposite from the dies 515 and 517. The interconnects 541 may comprise solder bumps or the like. In an embodiment, the interconnects 541 may be electrically coupled to the top side of the interposer 510 by through silicon vias (TSVs) (which are not shown for simplicity).

Referring now to FIG. 5B, a cross-sectional illustration of a multi-die module 500 is shown, in accordance with an additional embodiment. The multi-die module 500 in FIG. 5B may be substantially similar to the multi-die module 500 in FIG. 5A, with the exception of the construction of the central saw street 535. Instead of having a seal ring, the saw street 535 only includes a voided region. The omission of the seal ring is possible since the saw street 535 will not be singulated or otherwise cut. As such, there does not need to be a seal ring in order to prevent the propagation of cracks, stresses, or the like.

Referring now to FIG. 5C, a cross-sectional illustration of a computing system 590 is shown, in accordance with an embodiment. In an embodiment, the computing system 590 comprises a board 591, such as a printed circuit board (PCB). In an embodiment, the board 591 is coupled to a package substrate 593 by interconnects 592. The interconnects 592 may be solder interconnects, sockets, or the like. In an embodiment a multi-die module 500 is coupled to the package substrate 593 through interconnects 541.

The multi-die module 500 may be substantially similar to the multi-die module 500 described above with respect to FIGS. 5A or 5B. In the particular embodiment shown in FIG. 5C, the multi-die module 500 is similar to the multi-die module 500 in FIG. 5A. That is, the central saw street 535 has a seal ring. In an embodiment, the multi-die module 500 may comprise an interposer 510 with a first region 501A and a second region 501B. Dies 515 and 517 may be coupled to the interposer through interconnects 512. An overmold 542 may be provided around the dies 515 and 517, and around the interconnects 512.

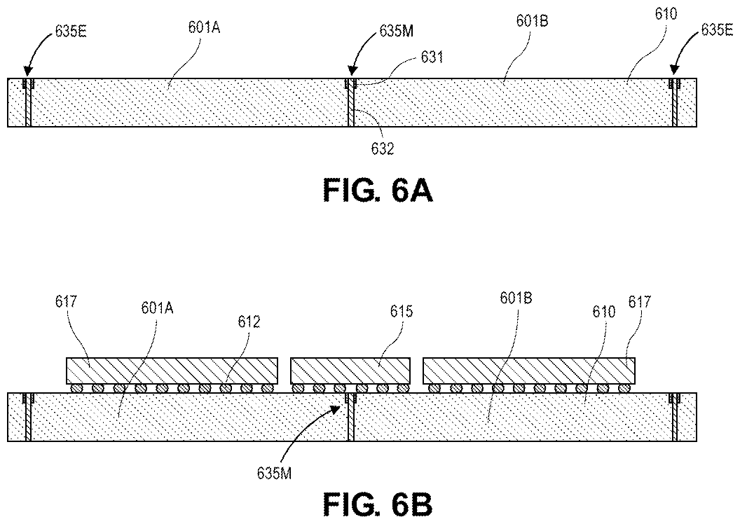

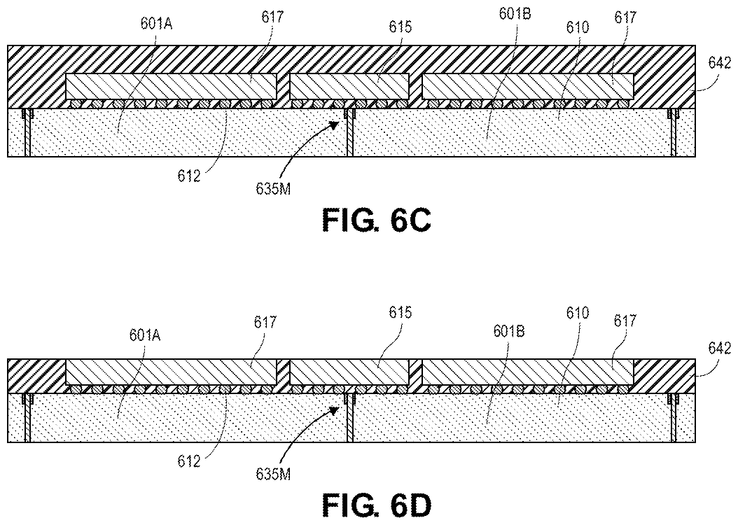

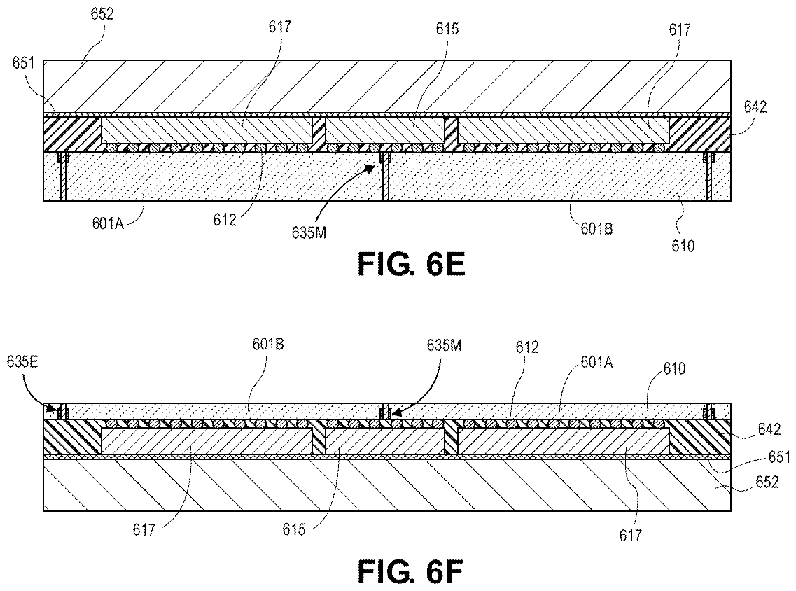

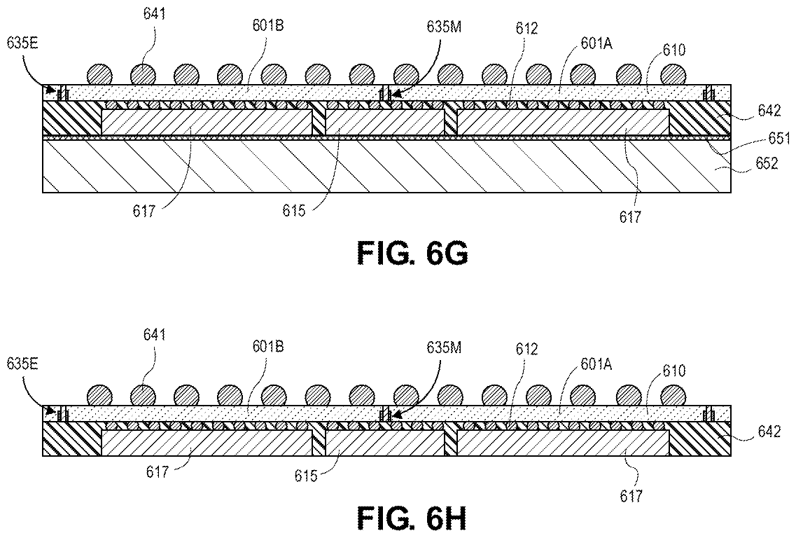

Referring now to FIGS. 6A-6I, a series of cross-sectional illustrations depicting a process for forming a multi-die module is shown, in accordance with an embodiment. The multi-die module in FIGS. 6A-6I may be substantially similar to the multi-die module 500 in FIG. 5A. Though, it is to be appreciated that a multi-die module with a structure similar to that of FIG. 5B may also be formed with similar processing operations. Additionally, the layout of the multi-die module may be similar to that of the layout shown in FIG. 4A or the layout shown in FIG. 4B.

Referring now to FIG. 6A, a cross-sectional illustration of an interposer 610 is shown, in accordance with an embodiment. The interposer 610 may be a silicon interposer or the like. In an embodiment, the interposer 610 may be patterned with one or more lithography operations in order to form a first region 601A and a second region 601B. The first region 601A and the second region 601B may include conductive routing (not shown). The first region 601A and the second region 601B may each have the footprint of a single reticle of the lithography system.

In an embodiment, the first region 601A is separated from the second region 601B by a middle saw street 635M. The saw street 635M may include a voided region 632 and a seal ring 631. While referred to as a saw street 635M, it is to be appreciated that the region of saw street 635M will not undergo any singulation, scribing, cutting, or the like. In an embodiment, edge saw streets 635E may be provided towards the edges of the interposer 510. While a multi-die module is shown in FIGS. 6A-6I, it is to be appreciated that a single larger interposer 610 may accommodate a plurality of multi-die modules, which are subsequently singulated from each other along the edge saw streets 635E.

Referring now to FIG. 6B, a cross-sectional illustration of the multi-die module after dies 615 and 617 are attached is shown, in accordance with an embodiment. In an embodiment, die 615 may be a hub die, an SoC, a memory die, or the like. Dies 617 may be compute dies. In an embodiment, the dies 617 are coupled to the die 615 through routing on the interposer 610. The dies 615 and 617 may be coupled to the interposer 610 through interconnects 612.

In an embodiment, the die 615 may span across the middle saw street 635M. The die 615 may be coupled to both the first region 601A and the second region 601B. However, it is to be appreciated that there are no interconnects 612 directly over the middle saw street 635M. While conductive routing in the first region 601A is electrically isolated from the conductive routing in the second region 601B by the middle saw street 635M, electrical connections between the first region 601A and the second region 601B may be formed across the die 615.

Referring now to FIG. 6C, a cross-sectional illustration of the multi-die module after an overmold layer 642 is applied is shown, in accordance with an embodiment. The overmold layer 642 may be applied with a molding process or any other suitable material deposition process. The overmold layer 642 may be provided over the dies 615 and 617, and around the interconnects 612. Though, in some embodiments, a CUF may be applied around the interconnects 612, and the overmold layer 642 may be applied over the dies 615 and 617 and around CUF. In an embodiment, the overmold layer 642 has a thickness that is greater than the standoff height of the dies 615 and 617.

Referring now to FIG. 6D, a cross-sectional illustration of the multi-die module after the overmold layer 642 is planarized is shown, in accordance with an embodiment. In an embodiment, the overmold layer 642 may be recessed with a chemical mechanical planarization (CMP) process, or the like. The overmold layer 642 is recessed to the point where the backside surfaces of the dies 615 and 617 are exposed.

Referring now to FIG. 6E, a cross-sectional illustration of the multi-die module after a carrier 652 is attached is shown, in accordance with an embodiment. In an embodiment, the carrier 652 is attached to the dies 615 and 617 through an adhesive layer 651. The carrier 652 may be a glass carrier, a silicon carrier, or any other rigid substrate material.

Referring now to FIG. 6F, a cross-sectional illustration of the multi-die module after the interposer 610 is recessed is shown, in accordance with an embodiment. The interposer 610 may be recessed with a CMP process or the like. The recessing process may allow for TSVs (not shown) through the interposer 610 to be exposed.

Referring now to FIG. 6G, a cross-sectional illustration of the multi-die module after interconnects 641 are attached to the interposer 610 is shown, in accordance with an embodiment. The interconnects 641 may be mid-level interconnects, such as solder balls or the like.

Referring now to FIG. 6H, a cross-sectional illustration of the multi-die module after the carrier 652 is removed is shown, in accordance with an embodiment. In an embodiment, the carrier 652 may be removed by deactivating the adhesion layer 651 (e.g., with heat, electromagnetic radiation exposure, or the like).

Referring now to FIG. 6I, a cross-sectional illustration of the multi-die module after a singulation process is shown, in accordance with an embodiment. In an embodiment, the singulation process involves cutting through the edge saw streets 635E (e.g., with a mechanical sawing process, an etching process, or the like). As shown, the edge saw streets 635E may only have a single seal ring on the interior of the edge saw streets 635E.

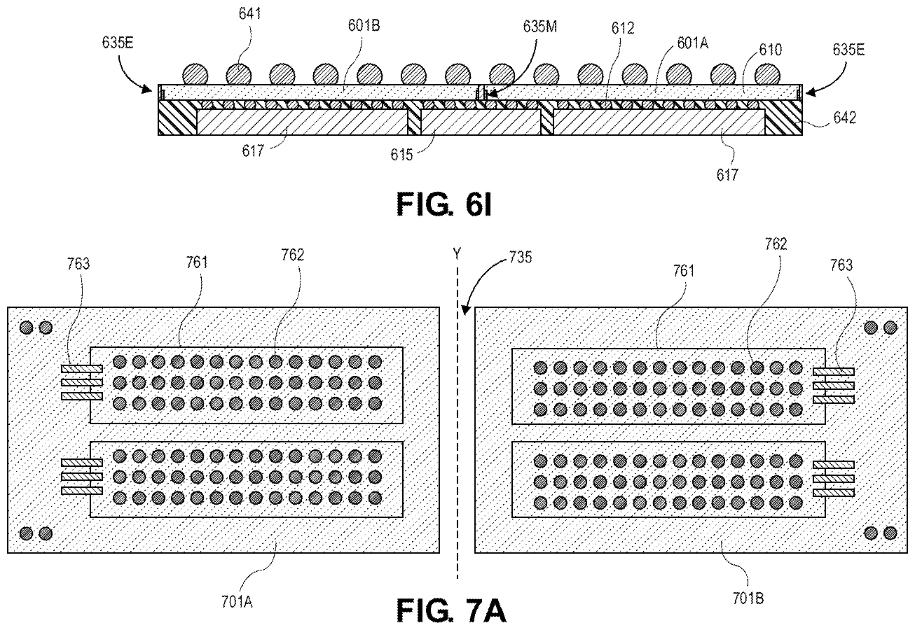

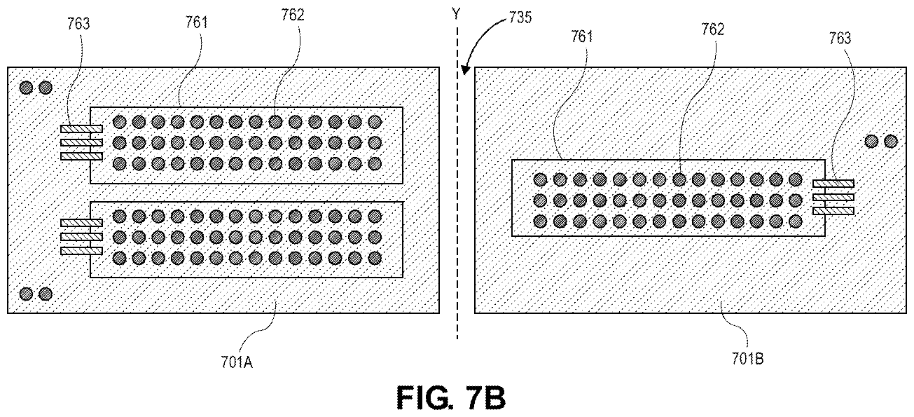

Referring now to FIG. 7A, a plan view illustration of an interposer is shown, in accordance with an embodiment. The interposer may comprise a first region 701A and a second region 701B. A saw street 735 may be provided between the first region 701A and the second region 701B. In an embodiment, each region may comprise a die footprint 761 with a bump pattern 762, routing or the like. Die-to-die interconnects 763 may also be provided in each of the first region 701A and the second region 701B.

In an embodiment, the first region 701A may be a mirror image of the second region 701B across the centerline Y. Since they are mirror images of each other, a single reticle may be used in order to pattern the first region 701A and the second region 701B. For example, the lithography exposure tool may have functionality in order to mirror the image of the reticle in some embodiments.

Referring now to FIG. 7B, a plan view illustration of an interposer is shown, in accordance with an additional embodiment. In an embodiment, the first region 701A may have a different layout than the second region 701B. As such, there may need to be two different reticles used to form the interposer of FIG. 7B.

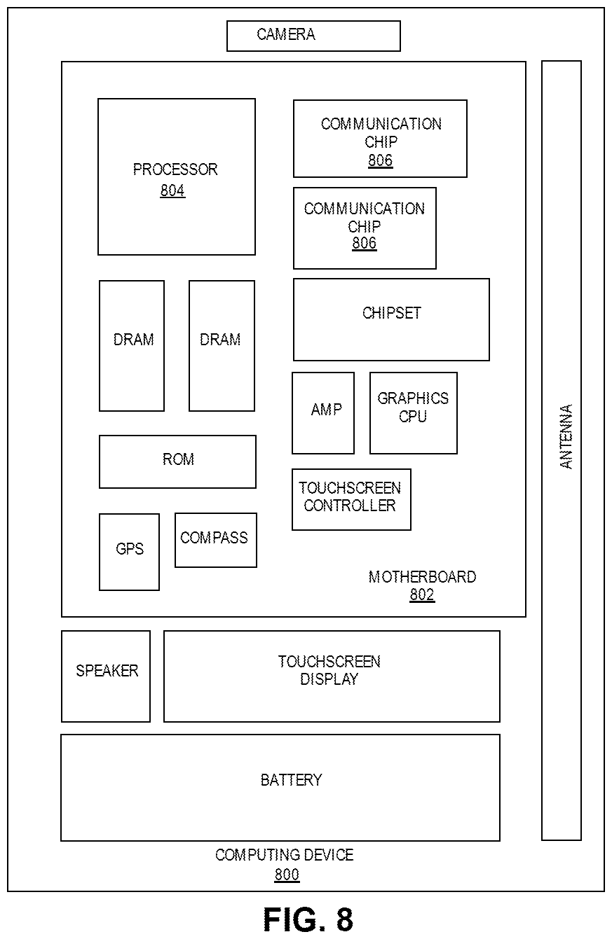

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of a multi-die module that comprises an interposer with a first region and a second region that are spaced apart by a saw street, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of a multi-die module that comprises an interposer with a first region and a second region that are spaced apart by a saw street, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a multi-die module, comprising: an interposer, wherein the interposer comprises: a first region; and a second region, wherein the first region is spaced apart from the second region by a saw street; a first die over the interposer, wherein the first die is positioned over the saw street; a second die adjacent to a first end of the first die; and a third die adjacent to a second end of the first die opposite from the first end.

Example 2: the multi-die module of Example 1, wherein, within the interposer, electrical routing in the first region is electrically isolated from electrical routing in the second region by the saw street.

Example 3: the multi-die module of Example 2, wherein the first die provides a bridge between the electrical routing in the first region and the electrical routing in the second region.

Example 4: the multi-die module of Examples 1-3, wherein the saw street is

lined by a seal ring.

Example 5: the multi-die module of Examples 1-4, wherein the first region is a mirror image of the second region.

Example 6: the multi-die module of Examples 1-5, wherein the first region has a different layout than the second region.

Example 7: the multi-die module of Examples 1-6, wherein the first die is a system on a chip (SoC) and wherein the second die and the third die are compute dies.

Example 8: the multi-die module of Examples 1-7, wherein the first die is a compute die, and wherein the second die and the third die are systems on a chip (SoCs).

Example 9: the multi-die module of Examples 1-8, wherein no interconnect is provided over the saw street between the interposer and the first die.

Example 10: the multi-die module of Examples 1-9, wherein the interposer is coupled to a package substrate and a board.

Example 11: the multi-die module of Examples 1-10, wherein the multi-die module is part of a personal computer, a server, a mobile device, a tablet, or an automobile.

Example 12: an electronic package, comprising: a package substrate; an interposer coupled to the package substrate, wherein the interposer has a first region and a second region that is separated from the first region by a saw street, wherein the first region is a mirror image of the second region; and a die coupled to the interposer, wherein the die spans across the saw street.

Example 13: the electronic package of Example 12, wherein the interposer comprises silicon.

Example 14: the electronic package of Example 12 or Example 13, wherein the first region and the second region have footprints with an approximately 26 mm by approximately 33 mm form factor.

Example 15: the electronic package of Examples 12-14, wherein a width of the saw street is approximately 10 μm or less.

Example 16: the electronic package of Examples 12-15, wherein the saw street is lined by a seal ring.

Example 17: the electronic package of Examples 12-16, wherein the die is a system on a chip (SoC) or a compute die.

Example 18: a computing system, comprising: a board; a package substrate coupled to the board; and a multi-die module coupled to the package substrate, wherein the multi-die module comprises: an interposer with a multi-reticle form factor, wherein a saw street is provided between each reticle region; a first die over the interposer, wherein the first die spans across the saw street; a second die adjacent to the first die on the interposer; and a third die adjacent to the first die on the interposer.

Example 19: the computing system of Example 18, wherein a reticle form factor is approximately 26 mm by approximately 33 mm.

Example 20: the computing system of Example 18 or Example 19, wherein the first die is a compute die or a system on a chip (SoC).

What is claimed is:

1. A multi-die module, comprising:
an interposer, wherein the interposer comprises:
a first region; and
a second region, wherein the first region is spaced apart from the second region by a saw street;
a first die over the interposer, wherein the first die is positioned over the saw street;
a second die adjacent to a first end of the first die; and
a third die adjacent to a second end of the first die opposite from the first end.

2. The multi-die module of claim 1, wherein, within the interposer, electrical routing in the first region is electrically isolated from electrical routing in the second region by the saw street.

3. The multi-die module of claim 2, wherein the first die provides a bridge between the electrical routing in the first region and the electrical routing in the second region.

4. The multi-die module of claim 1, wherein the saw street is lined by a seal ring.

5. The multi-die module of claim 1, wherein the first region is a mirror image of the second region.

6. The multi-die module of claim 1, wherein the first region has a different layout than the second region.

7. The multi-die module of claim 1, wherein the first die is a system on a chip (SoC) and wherein the second die and the third die are compute dies.

8. The multi-die module of claim 1, wherein the first die is a compute die, and wherein the second die and the third die are systems on a chip (SoCs).

9. The multi-die module of claim 1, wherein no interconnect is provided over the saw street between the interposer and the first die.

10. The multi-die module of claim 1, wherein the interposer is coupled to a package substrate and a board.

11. The multi-die module of claim 1, wherein the multi-die module is part of a personal computer, a server, a mobile device, a tablet, or an automobile.

12. An electronic package, comprising:
a package substrate;
an interposer coupled to the package substrate, wherein the interposer has a first region and a second region that is separated from the first region by a saw street, wherein the first region is a mirror image of the second region; and
a die coupled to the interposer, wherein the die spans across the saw street.

13. The electronic package of claim 12, wherein the interposer comprises silicon.

14. The electronic package of claim 12, wherein the first region and the second region have footprints with an approximately 26 mm by approximately 33 mm form factor.

15. The electronic package of claim 12, wherein a width of the saw street is approximately 10 μm or less.

16. The electronic package of claim 12, wherein the saw street is lined by a seal ring.

17. The electronic package of claim 12, wherein the die is a system on a chip (SoC) or a compute die.

18. A computing system, comprising:
a board;
a package substrate coupled to the board; and
a multi-die module coupled to the package substrate, wherein the multi-die module comprises:
an interposer with a multi-reticle form factor, wherein a saw street is provided between each reticle region;
a first die over the interposer, wherein the first die spans across the saw street;
a second die adjacent to the first die on the interposer; and
a third die adjacent to the first die on the interposer.

19. The computing system of claim 18, wherein a reticle form factor is approximately 26 mm by approximately 33 mm.

20. The computing system of claim 18, wherein the first die is a compute die or a system on a chip (SoC).
